(19) United States
(12) Patent Application Publication
(10) Pub. No.: US 2024/0196757 A1
(43) Pub. Date: Jun. 13, 2024

(54) FAN-OUT WAFER-LEVEL PACKAGES AND ASSOCIATED PRODUCTION METHODS

(71) Applicant: Infineon Technologies AG, Neubiberg (DE)

(72) Inventors: Horst THEUSS, Wenzenbach (DE); Christian GEISSLER, Teugn (DE); Rainer Markus SCHALLER, Aichen (DE); Walter HARTNER, Bad Abbach (DE)

(21) Appl. No.: 18/526,239

(22) Filed: Dec. 1, 2023

(30) Foreign Application Priority Data
Dec. 12, 2022 (DE) 102022132967.4

(51) Int. Cl. H10N 50/10; H01L 21/56; H01L 23/00; H01L 23/31

(52) U.S. Cl. CPC H10N 50/10; H01L 21/561; H01L 23/3157; H01L 24/20; H01L 24/96; H01L 2224/214; H01L 2224/215; H01L 2224/96

(57) ABSTRACT

A fan-out wafer-level package contains a magnetic field sensor chip and an encapsulation material which at least partially encapsulates the magnetic field sensor chip. Further, the fan-out wafer-level package contains an external electrical contact element formed by a planar solderable metal coating, and an electrical redistribution layer arranged over the encapsulation material and electrically interconnecting the magnetic field sensor chip and the external electrical contact element.

### CROSS-REFERENCE TO RELATED APPLICATION

This application claims priority to German Patent Application No. 102022132967.4 filed on Dec. 12, 2022, the content of which is incorporated by reference herein in its entirety.

### TECHNICAL FIELD

The present disclosure relates to fan-out wafer-level packages and associated production methods.

### BACKGROUND

Magnetic field sensors can be used in various technical applications. In one example, magnetic field sensors are used in miniaturized camera modules, for example as may be contained in smartphones. Very recent technology in this field is based on actuator systems which are assembled from coils, magnets, and sensors. Such systems are able to detect positions, distances, and angles and use measured data to suitably move system components such as optical lenses, for example. In this context, target applications can be optical image stabilization, autofocus, or optical zoom, amongst others. On account of the continual miniaturization of the aforementioned systems, ever higher demands are placed on the size and accuracy of the sensors used therein. Manufacturers and developers of corresponding devices constantly endeavor to improve their products. In this case, it may be of particular interest to provide particularly small sensor components which provide high measurement accuracies despite their miniaturization.

### SUMMARY

Various aspects relate to a fan-out wafer-level package. The fan-out wafer-level package includes a magnetic field sensor chip and an encapsulation material which at least partially encapsulates the magnetic field sensor chip. The fan-out wafer-level package also includes an external electrical contact element formed by a planar solderable metal coating. The fan-out wafer-level package also includes an electrical redistribution layer arranged over the encapsulation material and electrically interconnecting the magnetic field sensor chip and the external electrical contact element.

Various aspects relate to a method for producing a fan-out wafer-level package. The method includes a formation of a plurality of magnetic field sensor chips in a semiconductor wafer and a division of the semiconductor wafer into a plurality of singulated magnetic field sensor chips. The method also includes an encapsulation of a plurality of singulated magnetic field sensor chips in an encapsulation material, with a reconfigured wafer being formed. The method also includes a formation of an electrical redistribution layer over the encapsulation material and a formation of a planar solderable metal coating over the electrical redistribution layer. The method also includes a division of the reconfigured wafer into a plurality of fan-out wafer-level packages, wherein each singulated fan-out wafer-level package includes a magnetic field sensor chip and an external electrical contact element formed from a part of the planar solderable metal coating.

### BRIEF DESCRIPTION OF THE DRAWINGS

In what follows, methods and devices according to the disclosure are explained in detail with reference to drawings. The elements shown in the drawings are not necessarily rendered in a manner true to scale relative to one another. Identical reference signs may denote identical components.

FIG. 1 shows a flowchart of a method for producing a fan-out wafer-level package according to the disclosure.

FIGS. 2A to 2H schematically show cross-sectional side views of a method for producing a fan-out wafer-level package 200 according to the disclosure.

FIGS. 3A to 3I schematically show cross-sectional side views of a method for producing a fan-out wafer-level package 300 according to the disclosure.

FIGS. 4A and 4B schematically show a cross-sectional side view and a perspective view from below of a fan-out wafer-level package 400 according to the disclosure.

FIGS. 5A and 5B schematically show a cross-sectional side view and a view from below of a fan-out wafer-level package 500 according to the disclosure.

FIG. 6 schematically shows a cross-sectional side view of a fan-out wafer-level package 600 according to the disclosure.

FIG. 7 schematically shows a cross-sectional side view of a fan-out wafer-level package 700 according to the disclosure.

### DETAILED DESCRIPTION

In the following description, reference is made to the accompanying drawings. The drawings illustrate concrete implementations in which the present disclosure can be implemented in practice by way of example. The following detailed description should not be understood in a limiting sense here. For the sake of simplicity, properties of device or method elements may be described in detail in only one of the figures. However, it is clear that the described properties may also apply to similar elements in the other figures.

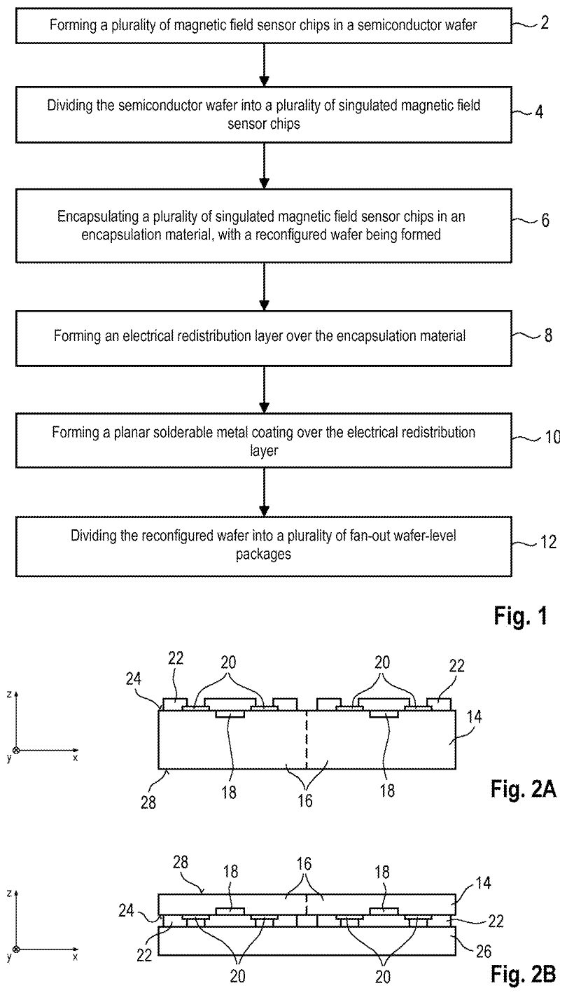

FIG. 1 shows a flowchart of a method for producing a fan-out wafer-level package according to the disclosure. The method is illustrated in a general way in order to describe aspects of the disclosure qualitatively. The method may include further aspects which are described in conjunction with other figures described herein. The method can be used to produce every fan-out wafer-level package according to the disclosure described herein.

At 2, a plurality of magnetic field sensor chips can be formed in a semiconductor wafer. At 4, the semiconductor wafer can be divided into a plurality of singulated magnetic field sensor chips. At 6, a plurality of singulated magnetic field sensor chips can be encapsulated in an encapsulation material, with a reconfigured wafer being formed. At 8, an electrical redistribution layer can be formed over the encapsulation material. At 10, a planar solderable metal coating can be formed over the electrical redistribution layer. At 12, the reconfigured wafer can be divided into a plurality of fan-out wafer-level packages. Each singulated fan-out wafer-level package may contain a magnetic field sensor chip and an external electrical contact element formed from a part of the planar solderable metal coating.

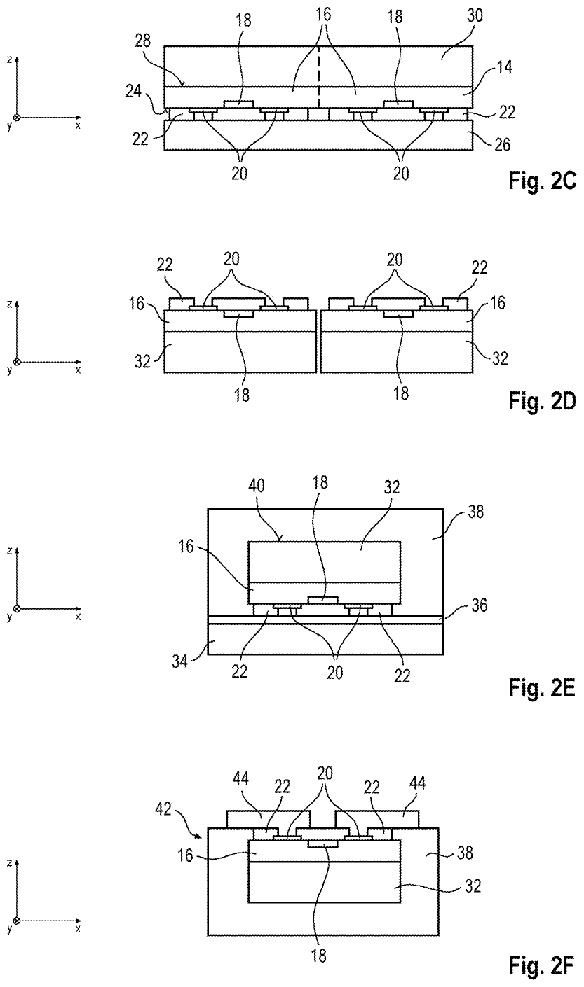

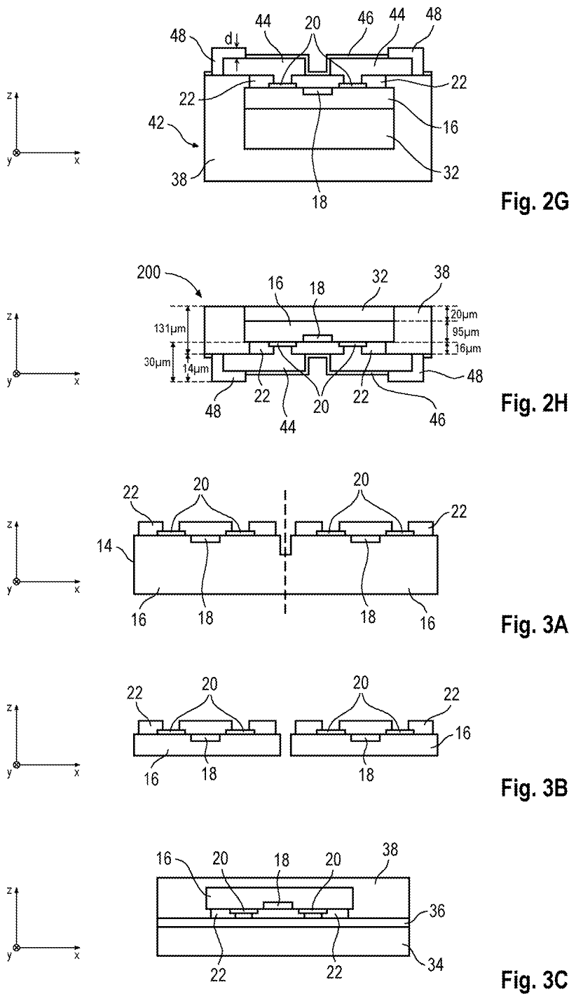

FIGS. 2A-2H show cross-sectional side views of a method for producing a fan-out wafer-level package 200 according to the disclosure. The method in FIG. 2 can be regarded as a more detailed version of the method in FIG. 1. In FIG. 2A, a semiconductor wafer (or a semiconductor panel) 14 possibly fabricated from silicon in particular can be provided. A plurality of magnetic field sensor chips (or magnetic field sensor dies) 16 can be formed in the semiconductor wafer 14. For the sake of simplicity, the shown example depicts only two magnetic field sensor chips 16, with a dashed line intending to indicate a boundary between the individual magnetic field sensor chips 16. However, it is clear that a much larger number of magnetic field sensor chips 16 can be formed in the semiconductor wafer 14.

Each magnetic field sensor chip 16 may comprise one or more sensor elements 18. The sensor elements 18 are not restricted to any specific sensor technology. In particular, the sensor elements 18 in the example shown can be TMR sensor elements; e.g., the magnetic field sensor chips 16 may correspond to (especially linear) TMR sensor chips. The sensor elements 18 may also have other implementations in further examples, for example as different xMR sensor elements (AMR sensor elements, GMR sensor elements), Hall sensor elements, vertical Hall sensor elements, fluxgate sensor elements, etc.

Each magnetic field sensor chip 16 may comprise one or more electrical contacts 20 which can provide an electrical connection to the internal electronic structures of the respective magnetic field sensor chip 16. A plastics layer 22 which may have openings at the positions of the electrical contacts 20 can be formed on the front side 24 of the semiconductor wafer 14. The plastics layer 22 can for example be fabricated from at least one out of a polyimide, an epoxy, and a photoresist (such as SU-8, for example).

In FIG. 2B, the semiconductor wafer 14 can be mounted by way of its front side 24 on a temporary carrier 26. By way of example, the carrier 26 can be a glass carrier. In a further step in FIG. 2B, the semiconductor wafer 14 can be thinned to a target thickness. To this end, material can be removed from the back side 28 of the semiconductor wafer 14 in the example shown, for example based on a grinding and polishing process. As measured in the z-direction, the target thickness of the semiconductor wafer 14 may have a value of less than approximately 100 μm.

In FIG. 2C, a protection layer (or back side protection layer) 30 can be arranged on the back side 28 of the (thinned) semiconductor wafer 14. The protection layer 30 can be fabricated from any suitable material. For example, the protection layer 30 may contain at least one out of a mold compound, a BSP (back side protection) tape, and a glass material. As measured in the z-direction, the protection layer 30 can have a dimension ranging from approximately 40 μm to approximately 100 μm.

The protection layer 30 can fulfil two functions. Firstly, the protection layer 30 can protect the back side 28 of the semiconductor wafer 14 during the further method and therebeyond from external influences, for example mechanical shocks. Secondly, the protection layer 30 can stabilize the (especially thinned) semiconductor wafer 14 for further processing steps and thereby prevent damage to the same. In this respect, the protection layer 30 can also be referred to as support or stabilization layer.

In FIG. 2D, the semiconductor wafer 14 and the protection layer 30 can be singulated into a plurality of magnetic field sensor chips 16. By way of example, at least one out of a mechanical dicing process, a stealth dicing process, a sawing process, etc. can be employed for this purpose. Following the division of the semiconductor wafer 14, each singulated magnetic field sensor chip 16 can comprise a part of the protection layer 30 as chip back side protection layer 32. Further, on its front side, each singulated magnetic field sensor chip 16 may comprise a part of the plastics layer 22. The temporary carrier 26 can be removed following the division of the semiconductor wafer 14.

In FIG. 2E, a plurality of singulated magnetic field sensor chips 16 can be arranged, on their front side, on a further temporary carrier 34, which may be similar to the temporary carrier 26 in FIG. 2B. In this case, an adhesive layer 36 can fasten the magnetic field sensor chip 16 to the carrier 34. In the example shown, only a single magnetic field sensor chip 16 is shown for the sake of simplicity. However, it is clear that a large number of magnetic field sensor chips 16 can be arranged on the carrier 34.

In a further step in FIG. 2E, the components arranged on the carrier 34 can be encapsulated by an encapsulation material 38. Encapsulation can be based on an eWLB (embedded wafer level ball grid array) technique, in particular. In the process, both the magnetic field sensor chips 16 and the chip back side protection layers 32 arranged on their back sides can be at least partially encapsulated by the encapsulation material 38. In the example shown, the side faces of the magnetic field sensor chips 16, the side faces of the chip back side protection layers 32, and the back sides 40 of the chip back side protection layers 32, in particular, may be covered by the encapsulation material 38. Moreover, the edges of the magnetic field sensor chips 16 facing the carrier 34 can be enclosed by the encapsulation material 38, and the side faces of the plastics layers 22 can be covered by the encapsulation material 38.

The encapsulation material 38 can be fabricated from at least one out of a mold compound, an epoxy or epoxy resin, a filled epoxy, a glass fiber-filled epoxy, an imide, a thermoplastic, a thermosetting polymer, a polymer mixture, etc. Various techniques can be used to produce encapsulation material 38, for example at least one out of compression molding, injection molding, powder molding, liquid molding, map molding, laminating, etc. In particular, the encapsulation material 38 may correspond to a mold compound with fine filler particles (“fine filler mold compound”). The fine filler particles can enable (in relation to the z-direction) a particularly thin encapsulation and particularly accurate grinding of the encapsulation material 38 during subsequent method steps. The encapsulation material 38 can form a housing for the components embedded therein and protect these from external influences, for example moisture or mechanical shocks. Thus, devices produced by the method in FIGS. 2A-2H can also be referred to as semiconductor housings or semiconductor packages.

The temporary carrier 34 and the adhesive layer 36 can be removed in FIG. 2F. Following the removal, the encapsulation material 38 with the components embedded therein can form a reconfigured wafer 42. In this case, a surface of the encapsulation material 38 and a surface of the plastics layer 22 may be arranged in essentially coplanar fashion, which is to say in a common plane.

In a further step in FIG. 2F, an electrical redistribution layer 44 can be fabricated on the top side of the reconfigured wafer 42. In this case, the electrically conductive material of the layer 44 can be deposited in the openings of the plastics layer 22 and on the (coplanar) surfaces of the encapsulation material 38 and the plastics layer 22. The electrical redistribution layer 44 can be fabricated from a metal (e.g., from copper) or a metal alloy based on one or more of electroplating, electroless plating, electrodeposition, etc. As measured in the z-direction, a thickness of the electrical redistribution layer 44 may have a value of approximately 10(±5) μm, for example.

In the example shown, at least one part of the electrical redistribution layer 44 can be arranged directly on the encapsulation material 38. That is to say, it is not mandatory for an additional dielectric layer to be arranged between the electrical redistribution layer 44 and the encapsulation material 38, as may be the case in conventional devices. As a result, an even smaller dimension of the arrangement in the z-direction can be achieved. Analogously, the electrical redistribution layer 44 can be arranged directly on the plastics layer 22. Thus, the plastics layer 22 can be arranged between the front side of the magnetic field sensor chip 16 and the electrical redistribution layer 44 and be at least partially embedded in the encapsulation material 38.

The electrical redistribution layer 44 may form one or more conductor tracks. The conductor tracks can fulfil the function of an electrical redistribution in order to electrically couple the electrical contacts 20 of the respective magnetic field sensor chip 16 to external contact elements (not yet shown). In other words, the electrical contacts 20 of the magnetic field sensor chip 16 can be made available at other positions using the conductor tracks. In the example shown, the electrical redistribution layer 44 can implement a redistribution of one or more of the electrical contacts 20 to external connectors which (as considered in the z-direction) may at least in part be arranged outside of a footprint of the magnetic field sensor chip 16. Devices with such spreading of the chip connectors, produced by the method in FIGS. 2A-2H, can be referred to as fan-out devices or fan-out packages. Since the devices moreover can be fabricated on the wafer level or panel level (e.g., based on an eWLB process), the devices can also be referred to as fan-out wafer-level devices or fan-out wafer-level packages.

In FIG. 2G, a solder mask 46 can be fabricated on the electrical redistribution layer 44. The solder mask 46 can be open at positions where external electrical contact elements are intended to be formed at a later stage. In an example, the solder mask 46 can be deposited extensively on the top side of the arrangement and subsequently be opened at the desired positions. The solder mask 46 can be fabricated in particular based on an atomic layer deposition (ALD) process. In comparison with a conventional mask, an ALD mask may have a lower height and reduce a warpage of the arrangement. The atomic layer deposition process can be a low-temperature process, in which temperatures of approximately 200° C. are not exceeded. The solder mask 46 can be fabricated from any suitable material, for example a nitride (e.g., SiN) and/or an oxide (e.g., Al₂O₃).

In a further step in FIG. 2G, one or more planar solderable metal coatings 48 can be fabricated over the electrical redistribution layer 44. In more detail, the planar solderable metal coating 48 can be deposited in the openings of the solder mask 46 and on the electrical redistribution layer 44. The deposited planar solderable metal coating 48 can be electrically connected to the electrical contacts 20 of the magnetic field sensor chip 16 via the electrical redistribution layer 44. That is to say, the respective magnetic field sensor chip 16 can be electrically contacted via the planar solderable metal coatings 48. In an example, the planar solderable metal coating 48 can be fabricated based on electroless plating. In this case, the top side of the solder mask 46 can remain uncovered by the material of the planar solderable metal coating 48.

In the case shown, the planar solderable metal coating 48 can comprise a planar first portion located in the x-y-plane and a planar second portion which covers the side faces of the electrically conductive redistribution layer 44. In examples described hereinbelow, the planar solderable metal coating 48 may be arranged in the x-y-plane only. In each of the aforementioned cases, the metal coating 48 or the portions forming the latter may each have a planar (or plane or flat or two-dimensional) and layer-type design.

The planar solderable metal coating 48 may be fabricated from a nonferromagnetic material. In particular, the planar solderable metal coating 48 may contain or be fabricated from a nonferromagnetic metal and/or a nonferromagnetic metal alloy. The planar solderable metal coating 48 can be formed from a single layer or from a layer stack with a plurality of stacked layers. A thickness d of the planar solderable metal coating 48 can be less than approximately 20 μm or less than approximately 15 μm or less than approximately 10 μm. In a typical example, the thickness d can range from approximately 2.5 μm to approximately 7 μm. The thickness d of the planar solderable metal coating 48 can have essentially a constant or uniform value.

In a specific example, the planar solderable metal coating 48 may contain or correspond to a layer stack with a first layer made of copper and a second layer made of at least one out of tin and silver. In a further specific example, the planar solderable metal coating 48 may contain or correspond to a layer stack with a first layer made of nickel-phosphorous and a second layer made of at least one out of palladium and gold. In this case, the nickel-phosphorus can contain a proportion of phosphorus of more than approximately 6 percent by weight.

The reconfigured wafer 42 can be thinned in FIG. 2H. To this end, material can be removed from the back side of the arrangement in the example shown, for example by way of a grinding process. In this case, the dimension of the arrangement in the z-direction can be reduced uniformly, with the result that the back sides of the chip back side protection layer 32 and encapsulation material 38 can be arranged in substantially coplanar fashion, which is to say in a common plane, after the thinning.

In a further step in FIG. 2H, the reconfigured wafer 42 can be divided into a plurality of fan-out wafer-level packages 200 according to the disclosure. By way of example, at least one out of a mechanical dicing process, a stealth dicing process, a sawing process, etc. can be employed for this purpose. Each singulated fan-out wafer-level package 200 can comprise a magnetic field sensor chip 16 with a chip back side protection layer 32. FIG. 2H illustrates a few example dimensions (in μm) of the fan-out wafer-level package 200 and its components. The dimensions indicated are merely by way of example and are not intended to be limiting in any way. Each of the dimensions indicated may deviate downward or upward by up to approximately 10%, for example.

The fan-out wafer-level packages described herein and the associated production methods according to the disclosure can provide the technical effects described below. Merely by way of example, reference may be made hereinbelow to the method in FIGS. 2A-2H. However, it is clear that the specified technical effects can also be provided by any other method described herein or by fan-out wafer-level packages according to the disclosure fabricated thereby.

Particularly thin fan-out wafer-level packages with particularly small dimensions in the z-direction can be produced by the method in FIG. 2. Several of the above-described process steps can contribute to this end. In this context: (1) A use of fine filler particles in the encapsulation material 38 can ensure a particularly thin encapsulation, (2) a use of the protection layer 30 can provide an adequate stabilization of the (especially thinned) semiconductor wafer 14, (3) the electrical redistribution layer 44 can be deposited without an additional dielectric intermediate layer directly on the encapsulation material 38, (4) a use of the plastics layer 22 can enable an encapsulation of the chip edges, and (5) the solder mask 46 can be embodied in the form of a particularly thin atomic layer deposition layer.

The magnetic field sensor chip 16 can be electrically contacted from outside of the fan-out wafer-level package 200 by way of the planar solderable metal coating 48. That is to say, the planar solderable metal coating 48 can form an external electrical contact element of the fan-out wafer-level package 200 or at least a part of such a contact element. The external electrical contact element can be arranged on the periphery of the fan-out wafer-level package 200. Further, the external electrical contact element can be configured to mechanically and/or electrically connect the fan-out wafer-level package 200 to another component (e.g., a printed circuit board).

The external electrical contact element can have a thickness in the z-direction of less than approximately 20 μm or less than approximately 15 μm or less than approximately 10 μm. In conventional devices, solder balls with a typical diameter ranging from approximately 200 μm to approximately 300 μm in particular can be used as external contact elements. In comparison with such conventional devices, the dimension of the fan-out wafer-level package 200 can accordingly be reduced by at least 180 μm in the z-direction. In general, an overall thickness of a fan-out wafer-level package according to the disclosure can be less than approximately 250 μm or less than approximately 225 μm or less than approximately 200 μm or less than approximately 175 μm or less than approximately 150 μm.

On account of the particularly small thicknesses in the z-direction, fan-out wafer-level packages according to the disclosure can be used in particularly space-saving fashion and in particularly small applications. In an example, the fan-out wafer-level packages can be used in miniaturized camera modules, as may be contained in smartphones for example. Such camera modules may be based on actuator systems which can be assembled from coils, magnets, and sensors. The actuator systems are able to detect positions, distances, and angles and use measured data to suitably move system components such as optical lenses, for example. In this context, the magnetic field sensor chip 16 can be configured to be used in one or more optical applications of the camera module, for example in at least one out of an optical image stabilization application, an autofocus application, an optical zoom application, etc.

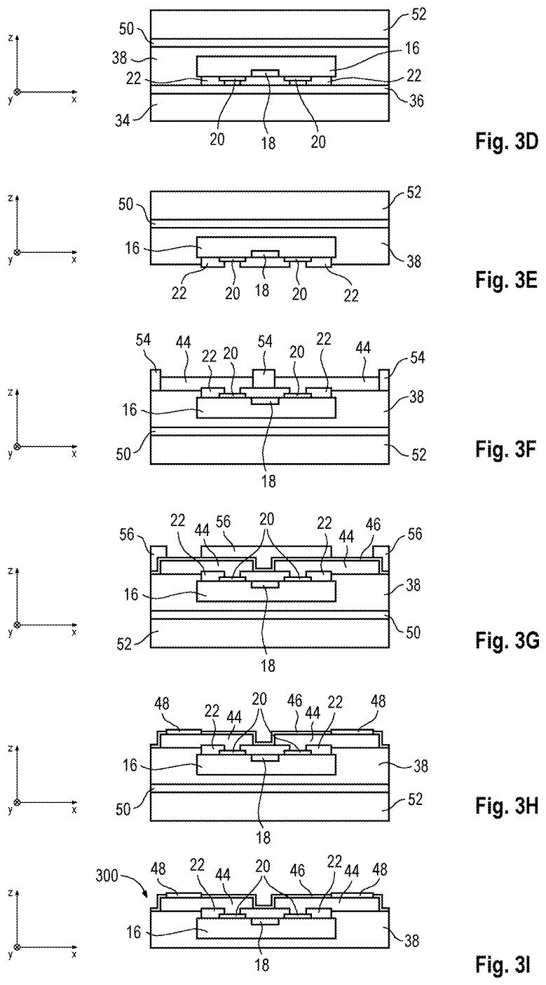

FIGS. 3A-3I show cross-sectional side views of a method for producing a fan-out wafer-level package 300 according to the disclosure. The method in FIGS. 3A-3I can be regarded as a more detailed version of the method in FIG. 1 and can be similar to the method in FIGS. 2A-2H at least in part. For the sake of simplicity, reference is made to the description of FIGS. 2A-2H in respect of similar method steps.

In FIG. 3A, a semiconductor wafer 14 with a plurality of magnetic field sensor chips 16 formed therein can be provided. Sensor elements 18, electrical contacts 20, and a plastics layer 22 can be arranged on the front side 24 of the semiconductor wafer 14.

In FIG. 3B, the semiconductor wafer 14 can optionally be thinned to a target thickness of approximately 100 μm, for example. Further, the semiconductor wafer 14 can be singulated into the plurality of magnetic field sensor chips 16, as indicated by a dashed line in FIG. 3A. For example, the singulation can be based on at least one out of a mechanical dicing process, a stealth dicing process, a sawing process, etc.

In FIG. 3C, singulated magnetic field sensor chips 16 can be fastened to a temporary carrier 34 by way of an adhesive layer 36 and be encapsulated by way of an encapsulating material 38. In contrast to FIG. 2E, a chip back side protection layer need not necessarily be arranged on the back side of the respective magnetic field sensor chip 16.

In FIG. 3D, the arrangement can be fastened to a further temporary carrier 52 using a further adhesive layer 50. The temporary carrier 34 and the adhesive layer 36 can be removed in FIG. 3E.

In FIG. 3F, an electrical redistribution layer 44 can be fabricated on the front side of the arrangement. In this case, the electrical redistribution layer 44 can be deposited in a structured fashion in particular by using a mask 54.

In FIG. 3G, the mask 54 can be removed and a solder mask 46 can be formed on the electrical redistribution layer 44. For example, the solder mask 46 can be fabricated based on an atomic layer deposition process at temperatures of below approximately 200° ° C. In a further step in FIG. 3G, a further mask 56 can be arranged over the solder mask 46. The mask 56 can be open at selected positions.

In FIG. 3H, the material of the solder mask 46 can be removed at the open positions of the mask 56, with the electrical redistribution layer 44 being exposed. In a further step in FIG. 3H, planar solderable metal coatings 48 can be formed on the exposed portions of the electrical redistribution layer 44. The deposited metal coatings 48 can be electrically connected to the electrical contacts 20 of the magnetic field sensor chip 16 via the electrical redistribution layer 44. In an example, the planar solderable metal coatings 48 can be produced based on an electroless plating process. The mask 56 can subsequently be removed.

The temporary carrier 52 and the adhesive layer 50 can be removed in FIG. 3I. The arrangement can subsequently be singulated into a multiplicity of fan-out wafer-level packages 300. The fan-out wafer-level packages 300 obtained may have dimensions and technical properties as already described in the context of FIGS. 2A-2H.

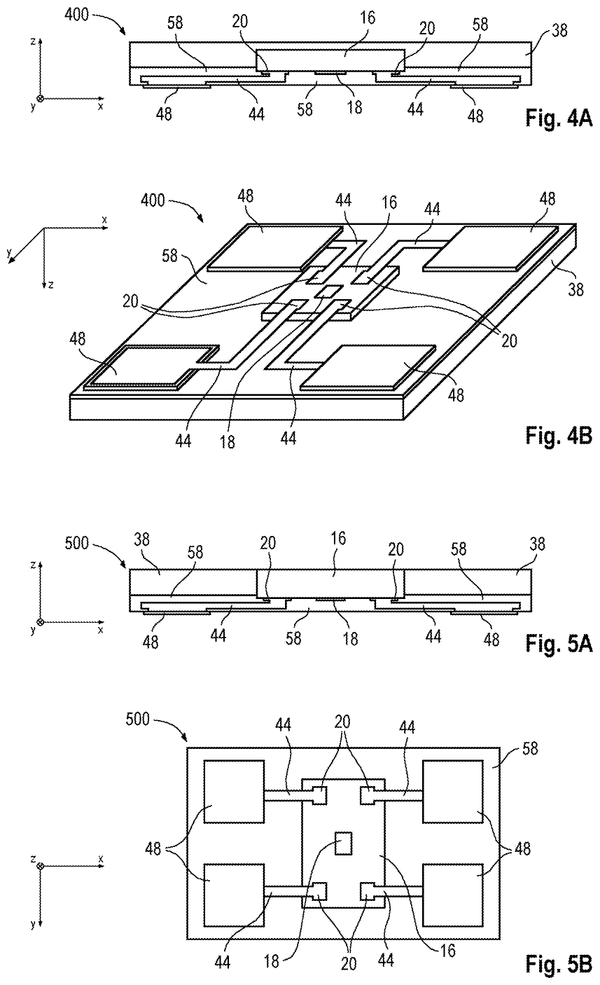

FIGS. 4A and 4B show a cross-sectional side view and a perspective view from below, respectively, of a fan-out wafer-level package 400 according to the disclosure. The fan-out wafer-level package 400 can be produced for example based on one of the methods in FIGS. 1 to 3. With regards to dimensions and technical features of the fan-out wafer-level package 400, reference is made to the description of FIGS. 1 to 3I for the sake of simplicity.

The fan-out wafer-level package 400 may contain, embedded in an encapsulation material 38, a magnetic field sensor chip 16 with electrical contacts 20 and at least one sensor element 18. An electrical redistribution layer 44 can be arranged over the front side of the magnetic field sensor chip 16 and can provide an electrical connection between the electrical contacts 20 and external electrical contact elements in the form of planar solderable metal coatings 48. For example, the fan-out wafer-level package 400 may have been fabricated based on an eWLB (embedded wafer level ball grid array) technique.

In contrast to devices described further above, the electrical redistribution layer 44 in the example shown need not necessarily be arranged directly on the encapsulation material 38; instead, it can optionally be embedded in a dielectric material 58 at least in part and be electrically insulated by the latter. However, the electrical redistribution layer 44 may also be formed directly on the encapsulation material 38 in further examples.

It is evident from FIG. 4B that the fan-out wafer-level package 400 can have a substantially rectangular or square footprint when considered in the z-direction. What can also be identified is that the electrical redistribution layer 44 may comprise a plurality of conductor tracks which can provide an electrical redistribution of the electrical contacts 20 of the magnetic field sensor chip 16 on the external electrical contact elements placed in the fan-out region or on the planar solderable metal coatings 48.

FIGS. 5A and 5B show a cross-sectional side view and a view from below, respectively, of a fan-out wafer-level package 500 according to the disclosure. The fan-out wafer-level package 500 can be similar, at least in part, to the fan-out wafer-level package 400 in FIGS. 4A and 4B. In contrast to FIGS. 4A and 4B, the back side of the magnetic field sensor chip 16 is possibly not covered by the encapsulation material 38. The back side of the encapsulation material 38 and the back side of the magnetic field sensor chip 16 may essentially be located in a common plane, which is to say may be arranged in coplanar fashion.

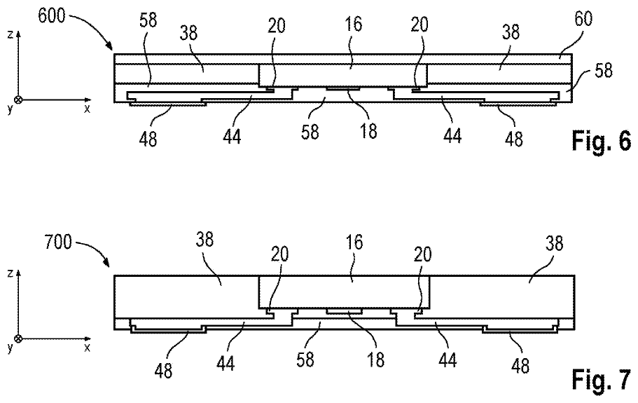

The fan-out wafer-level package 600 in FIG. 6 can be similar, at least in part, to the fan-out wafer-level package 500 in FIGS. 5A and 5B. In contrast to FIGS. 5A and 5B, the back side of the magnetic field sensor chip 16 not covered by the encapsulation material 38 may be protected by a passivation layer 60 arranged thereon. In an example, the passivation layer 60 may contain or be fabricated from a nitride (e.g., SiN).

The fan-out wafer-level package 700 in FIG. 7 can be similar, at least in part, to fan-out wafer-level packages according to the disclosure described above. By way of example, the fan-out wafer-level package 700 could have been fabricated based on the method in FIGS. 2A-2H. In contrast to the examples in FIGS. 5A, 5B, and 6, the electrical redistribution layer 44 of the fan-out wafer-level package 700 may be arranged directly on the encapsulation material 38, in order to achieve a lower installation height of the device. Further, the edges of the magnetic field sensor chip 16 facing the electrical redistribution layer 44 may be enclosed by the encapsulation material 38.

### Aspects

Fan-out wafer-level packages and associated production methods are explained hereinbelow based on aspects.

Aspect 1 is a fan-out wafer-level package, comprising: a magnetic field sensor chip; an encapsulation material which at least partly encapsulates the magnetic field sensor chip; an external electrical contact element formed by a planar solderable metal coating; and an electrical redistribution layer arranged over the encapsulation material and electrically interconnecting the magnetic field sensor chip and the external electrical contact element.

Aspect 2 is fan-out wafer-level package according to Aspect 1, wherein the magnetic field sensor chip comprises at least one TMR sensor element.

Aspect 3 is fan-out wafer-level package according to Aspect 1 or 2, wherein the planar solderable metal coating is fabricated from a nonferromagnetic material.

Aspect 4 is fan-out wafer-level package according to any of the preceding aspects, wherein the planar solderable metal coating comprises a layer stack with a first layer made of copper and a second layer made of at least one out of tin and silver.

Aspect 5 is fan-out wafer-level package according to any of the preceding aspects, wherein the planar solderable metal coating comprises a layer stack with a first layer made of nickel-phosphorous and a second layer made of at least one out of palladium and gold.

Aspect 6 is a fan-out wafer-level package according to Aspect 5, wherein the nickel-phosphorus contains a proportion of phosphorus of more than 6 percent by weight.

Aspect 7 is a fan-out wafer-level package according to any of the preceding aspects, wherein a thickness of the external electrical contact element is less than 20 micrometers.

Aspect 8 is a fan-out wafer-level package according to any of the preceding aspects, wherein an overall thickness of the fan-out wafer-level package is less than 250 micrometers.

Aspect 9 is a fan-out wafer-level package according to any of the preceding aspects, wherein at least one part of the electrical redistribution layer is arranged directly on the encapsulation material.

Aspect 10 is a fan-out wafer-level package according to any of the preceding aspects, wherein edges of the magnetic field sensor chip facing the electrical redistribution layer are enclosed by the encapsulation material.

Aspect 11 is a fan-out wafer-level package according to any of the preceding aspects, further comprising: a plastics layer arranged between a front side of the magnetic field sensor chip and the electrical redistribution layer and at least partially encapsulated by the encapsulation material.

Aspect 12 is a fan-out wafer-level package according to Aspect 11, wherein the electrical redistribution layer is arranged directly on the plastics layer.

Aspect 13 is a fan-out wafer-level package according to Aspect 11 or 12, wherein the plastics layer comprises at least one out of a polyimide, an epoxy, and a photoresist.

Aspect 14 is a fan-out wafer-level package according to any of the preceding aspects, further comprising: a solder mask which is fabricated based on atomic layer deposition, arranged on the electrical redistribution layer, and open at positions of the planar solderable metal coating.

Aspect 15 is a fan-out wafer-level package according to Aspect 14, wherein the solder mask comprises at least one out of silicon nitride and aluminum oxide.

Aspect 16 is a fan-out wafer-level package according to any of the preceding aspects, further comprising: a chip back side protection layer arranged on a back side of the magnetic field sensor chip and at least partially encapsulated by the encapsulation material.

Aspect 17 is a fan-out wafer-level package according to any of the preceding aspects, wherein dimensions of the fan-out wafer-level package are configured for the purpose of integrating the fan-out wafer-level package in a camera module of a smartphone.

Aspect 18 is a fan-out wafer-level package according to Aspect 17, wherein the magnetic field sensor chip is configured to be used in at least one out of an optical image stabilization application, an autofocus application, and an optical zoom application of the camera module.

Aspect 19 is a method for producing a fan-out wafer-level package, comprising: forming a plurality of magnetic field sensor chips in a semiconductor wafer; dividing the semiconductor wafer into a plurality of singulated magnetic field sensor chips; encapsulating a plurality of singulated magnetic field sensor chips in an encapsulation material, with a reconfigured wafer being formed; forming an electrical redistribution layer over the encapsulation material; forming a planar solderable metal coating over the electrical redistribution layer; and dividing the reconfigured wafer into a plurality of fan-out wafer-level packages, wherein each singulated fan-out wafer-level package comprises a magnetic field sensor chip and an external electrical contact element formed from a part of the planar solderable metal coating.

Aspect 20 is a method according to Aspect 19, further comprising: thinning the semiconductor wafer before the semiconductor wafer is divided; and arranging a protection layer on a back side of the thinned semiconductor wafer, wherein: following the division of the semiconductor wafer, each singulated magnetic field sensor chip comprises a part of the protection layer as chip back side protection layer, and the chip back side protection layer is at least partially encapsulated by the encapsulation material.

Aspect 21 is a method according to Aspect 19 or 20, further comprising: forming a plastics layer on a front side of the semiconductor wafer before the semiconductor wafer is divided, wherein: following the division of the semiconductor wafer, each singulated magnetic field sensor chip comprises a part of the plastics layer on a front side of the respective magnetic field sensor chip, and the electrical redistribution layer is formed directly on the plastics layer and directly on the encapsulation material.

Aspect 22 is a method according to any of Aspects 19 to 21, further comprising: forming a solder mask on the electrical redistribution layer based on an atomic layer deposition process.

Aspect 23 is a method according to Aspect 22, wherein the solder mask is formed based on a low-temperature process at a temperature of less than 200° C.

Although specific implementations have been depicted and described herein, it is obvious to a person skilled in the art that a multiplicity of alternative and/or equivalent implementations can replace the specific implementations shown and described, without departing from the scope of the present disclosure. This application is intended to cover all adaptations or variations of the specific implementations discussed herein. Therefore, the intention is for this disclosure to be restricted only by the claims and the equivalents thereof.

1. A fan-out wafer-level package, comprising:
a magnetic field sensor chip;
an encapsulation material which at least partly encapsulates the magnetic field sensor chip;
an external electrical contact element formed by a planar solderable metal coating; and
an electrical redistribution layer arranged over the encapsulation material and electrically interconnecting the magnetic field sensor chip and the external electrical contact element.

2. The fan-out wafer-level package as claimed in claim 1, wherein the magnetic field sensor chip comprises at least one TMR sensor element.

3. The fan-out wafer-level package as claimed in claim 1, wherein the planar solderable metal coating is fabricated from a nonferromagnetic material.

4. The fan-out wafer-level package as claimed in claim 1, wherein the planar solderable metal coating comprises a layer stack with a first layer made of copper and a second layer made of at least one of tin or silver.

5. The fan-out wafer-level package as claimed in claim 1, wherein the planar solderable metal coating comprises a layer stack with a first layer made of nickel-phosphorus and a second layer made of at least one of palladium or gold.

6. The fan-out wafer-level package as claimed in claim 5, wherein the nickel-phosphorus contains a proportion of phosphorus of more than 6 percent by weight.

7. The fan-out wafer-level package as claimed in claim 1, wherein a thickness of the external electrical contact element is less than 20 micrometers, and
wherein an overall thickness of the fan-out wafer-level package is less than 250 micrometers.

8. (canceled)

9. The fan-out wafer-level package as claimed in claim 1, wherein at least one part of the electrical redistribution layer is arranged directly on the encapsulation material.

10. The fan-out wafer-level package as claimed in claim 1, wherein edges of the magnetic field sensor chip facing the electrical redistribution layer are enclosed by the encapsulation material.

11. The fan-out wafer-level package as claimed in claim 1, further comprising:
a plastics layer arranged between a front side of the magnetic field sensor chip and the electrical redistribution layer and at least partially encapsulated by the encapsulation material,
wherein the electrical redistribution layer is arranged directly on the plastics layer and
wherein the plastics layer comprises at least one of a polyimide, an epoxy, or a photo resist.

12. (canceled)

13. (canceled)

14. The fan-out wafer-level package as claimed in claim 1, further comprising:
a solder mask which is fabricated based on atomic layer deposition, wherein the solder mask is arranged on the electrical redistribution layer, and open at positions of the planar solderable metal coating.

15. The fan-out wafer-level package as claimed in claim 14, wherein the solder mask comprises at least one of silicon nitride or aluminum oxide.

16. The fan-out wafer-level package as claimed in claim 1, further comprising:
a chip back side protection layer arranged on a back side of the magnetic field sensor chip and at least partially encapsulated by the encapsulation material.

17. The fan-out wafer-level package as claimed in claim 1, wherein dimensions of the fan-out wafer-level package are configured to integrate the fan-out wafer-level package in a camera module of a smartphone.

18. The fan-out wafer-level package as claimed in claim 17, wherein the magnetic field sensor chip is configured to be used in at least one of an optical image stabilization application, an autofocus application, or an optical zoom application of the camera module.

19. A method for producing a fan-out wafer-level package, comprising:
forming a plurality of magnetic field sensor chips in a semiconductor wafer;
dividing the semiconductor wafer into a plurality of singulated magnetic field sensor chips;
encapsulating a plurality of singulated magnetic field sensor chips in an encapsulation material, with a reconfigured wafer being formed;
forming an electrical redistribution layer over the encapsulation material;
forming a planar solderable metal coating over the electrical redistribution layer; and
dividing the reconfigured wafer into a plurality of fan-out wafer-level packages, wherein each singulated fan-out wafer-level package comprises a magnetic field sensor chip and an external electrical contact element formed from a part of the planar solderable metal coating.

20. The method as claimed in claim 19, further comprising:
thinning the semiconductor wafer before the semiconductor wafer is divided; and
arranging a protection layer on a back side of the thinned semiconductor wafer, wherein:
following the dividing of the semiconductor wafer, each singulated magnetic field sensor chip comprises a part of the protection layer as chip back side protection layer, and
the chip back side protection layer is at least partially encapsulated by the encapsulation material.

21. The method as claimed in claim 19, further comprising:
forming a plastics layer on a front side of the semiconductor wafer before the semiconductor wafer is divided, wherein:
following the dividing of the semiconductor wafer, each singulated magnetic field sensor chip comprises a part of the plastics layer on a front side of the respective magnetic field sensor chip, and
the electrical redistribution layer is formed directly on the plastics layer and directly on the encapsulation material.

22. The method as claimed in claim 19, further comprising:
forming a solder mask on the electrical redistribution layer based on an atomic layer deposition process.

23. The method as claimed in claim 22, wherein the solder mask is formed based on a low-temperature process at a temperature of less than 200° C.
